(19) United States
(12) Patent Application Publication
(10) Pub. No.: US 2021/0313169 A1
(43) Pub. Date: Oct. 7, 2021

(54) APPARATUSES FOR MANUFACTURING SEMICONDUCTOR DEVICES

(71) Applicant: Samsung Electronics Co., Ltd., Suwon-si (KR)

(72) Inventors: Hyunjae SONG, Hwaseong-si (KR); Kaoru YAMAMOTO, Seongnam-si (KR); Changhyun KIM, Seoul (KR); Shuji MORIYA, Hwaseong-si (KR); Jungsoo YOON, Hwaseong-si (KR); Soyoung LEE, Yongin-si (KR); Changseok LEE, Seoul (KR)

(73) Assignee: Samsung Electronics Co., Ltd., Suwon-si (KR)

(21) Appl. No.: 17/208,216

(22) Filed: Mar. 22, 2021

(30) Foreign Application Priority Data
Apr. 2, 2020 (KR) 10-2020-0040481

(51) Int. Cl. H01L 21/02; H01L 21/428; H01L 21/3213; H01J 37/32

(52) U.S. Cl. CPC H01L 21/0231; H01L 21/428; H01L 2021/60105; H01J 37/32192; H01L 21/32136

(57) ABSTRACT

Provided are apparatuses for manufacturing semiconductor devices. An apparatus includes a reaction chamber having a stage to be loaded on a substrate, wherein set plasma is formed over the stage, a plurality of gas supply lines connected to the reaction chamber, flow controllers formed on the plurality of gas supply lines, respectively, to control the amount of a gas supplied to the reaction chamber, and a gas splitter configured to supply a mixed gas to the flow controllers. The apparatus may be a thin film deposition apparatus using plasma and further include a flow control unit connected to the gas splitter and a gas supply source connected to the flow control unit.

### CROSS-REFERENCE TO RELATED APPLICATION

This application claims the benefit of Korean Patent Application No. 10-2020-0040481, filed on Apr. 2, 2020, in the Korean Intellectual Property Office, the disclosure of which is incorporated herein in its entirety by reference.

### BACKGROUND

### 1. Field

The disclosure relates to apparatuses for manufacturing semiconductor devices.

### 2. Description of Related Art

When a wafer with a large diameter is used to manufacture semiconductor devices, a relatively large number of semiconductor devices are produced from a single wafer so that a unit price of a semiconductor device may be reduced. When the diameter of the wafer increases, the environment of a process for manufacturing semiconductor devices may vary, and accordingly, it is necessary to adjust the process conditions according to the new environment. However, this adjustment of the process conditions may not be simple.

### SUMMARY

Provided are apparatuses configured to manufacture semiconductor devices, the apparatuses being capable of forming a thin film with a uniform thickness on a substrate by uniformly supplying a gas to the substrate, regardless of a size of the substrate.

Additional aspects will be set forth in part in the description which follows and, in part, will be apparent from the description, or may be learned by practice of the presented example embodiments of the disclosure.

According to some example embodiments, an apparatus includes a reaction chamber having a stage on which a substrate may be loaded, wherein the reaction chamber may be configured to have set plasma formed over the stage, a plurality of gas supply lines connected to the reaction chamber, flow controllers formed on the plurality of gas supply lines, respectively, to control the amount of a gas supplied to the reaction chamber, and a gas splitter configured to supply a mixed gas to the flow controllers.

In some embodiments, the apparatus may further include a flow control unit connected to the gas splitter and a gas supply source connected to the flow control unit.

According to some example embodiments, the flow control unit may include a first flow controller configured to control the supply amount of a first gas, a second flow controller configured to control the supply amount of a second gas, and a third flow controller configured to control the supply amount of a third gas different from the first and second gases.

According to some example embodiments, the gas splitter may include a first gas splitter connected to some of the plurality of flow controllers and a second gas splitter connected to the rest of the plurality of flow controllers.

According to some example embodiments, the plurality of flow controllers may be mass flow controllers (MFCs) and in another embodiment, the plurality of flow controllers may be pressure control valves (PCVs)

According to some example embodiments, connection positions of the plurality of gas supply lines with respect to the reaction chamber may be symmetrically distributed.

According to some example embodiments, the plurality of gas supply lines may be connected to be closer to an upper end of the reaction chamber than the stage.

According to some example embodiments, the plurality of gas supply lines may be connected to be closer to the stage than the upper end of the reaction chamber.

According to some example embodiments, the apparatus may further include, on the reaction chamber, a plasma generator having an RF or a frequency in a microwave region. The reaction chamber may be a chamber for thin film deposition.

According to some example embodiments, the apparatus includes a reaction chamber having a stage on which a substrate may be loaded, wherein the reaction chamber may be configured to have set plasma formed over the stage, a plurality of gas supply lines connected to the reaction chamber, and a plurality of flow control units configured to control the amount of a gas supplied to the reaction chamber and connected to the plurality of gas supply lines on a one-to-one basis, wherein each of the plurality of flow control units include a plurality of flow controllers.

In some embodiments, the plurality of flow controllers may be provided in a same number as different gas components supplied to the reaction chamber.

In some embodiments, the apparatus may further include a gas supply source for supplying a gas to each of the plurality of flow control units. The gas supply source may include gas supply units provided in a same number as the number of the plurality of flow controllers provided in the plurality of flow control units, respectively.

According to some example embodiments, the gas supply source may include a first gas supply unit for supplying a first gas to each of the plurality of flow supply units, and a second gas supply unit for supplying a second gas different from the first gas to each of the plurality of flow control units.

According to some example embodiments, the gas supply source may include a third gas supply unit for supplying a third gas different from the first and second gases to each of the plurality of flow control units.

According to some example embodiments, the plurality of gas supply lines may be connected to be closer to an upper end of the reaction chamber than the stage.

According to some example embodiments, the plurality of gas supply lines may be connected to be closer to the stage than an upper end of the reaction chamber.

In apparatuses according to some example embodiments, a portion of the plurality of gas supply lines may be connected to the reaction chamber between an upper end of the reaction chamber and the stage, and a rest the plurality of gas supply lines may be connected to the reaction chamber between the portion and the stage.

In some embodiments, a ratio (d/r) of a radius (r) of a plasma forming space inside the reaction chamber to a distance (d) between an upper end of the reaction chamber and the stage may be less than 1.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a plan view of a first semiconductor manufacturing apparatus according to some example embodiments;

FIG. 2 is a three-dimensional view of the first semiconductor manufacturing apparatus of FIG. 1;

FIG. 3 is a three-dimensional view showing a second semiconductor manufacturing apparatus according to some example embodiments;

FIG. 4 is a three-dimensional view showing a third semiconductor manufacturing apparatus according to some example embodiments;

FIG. 5 is a plan view showing a case in which a portion of a plurality of gas supply lines and the rest thereof in the third semiconductor manufacturing apparatus of FIG. 4 are symmetry and differently arranged from FIG. 4

FIG. 6 is a three-dimensional view showing a fourth semiconductor manufacturing apparatus according to some example embodiments;

FIG. 7 is a front view of a first region including a reaction chamber and a plasma generator of FIG. 2;

FIG. 8 is a front view showing a case in which gas supply lines in FIG. 7 are connected closer to a stage than an upper end of the reaction chamber;

FIG. 9 is a front view of a case in which FIGS. 7 and 8 are combined;

FIG. 10 is a three-dimensional view of a fifth semiconductor manufacturing apparatus according to some example embodiments;

FIG. 11 is a plan view of a sixth semiconductor manufacturing apparatus according to some example embodiments; and

FIG. 12 is a three-dimensional view of the sixth semiconductor manufacturing apparatus of FIG. 11 according to some example embodiments.

### DETAILED DESCRIPTION

Reference will now be made in detail to some embodiments, some of which are illustrated in the accompanying drawings, wherein like reference numerals refer to like elements In this regard, the present embodiments may have different forms and should not be construed as being limited to the descriptions set forth herein. Accordingly, some example embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Hereinafter, an apparatus for manufacturing a semiconductor device according to some example embodiments will be described in detail with reference to the accompanying drawings. In this process, a thickness of a layer or thicknesses of regions illustrated in the drawings may be exaggerated for clarity of the present inventive concept. In addition, the following example embodiments described below are merely illustrative, and various modifications are possible from some example embodiments of the present disclosure. Furthermore, hereinafter, in a layer structure, expressions such as “upper portion” or “above” are referred to as being on while in contact as well as on while not in contact.

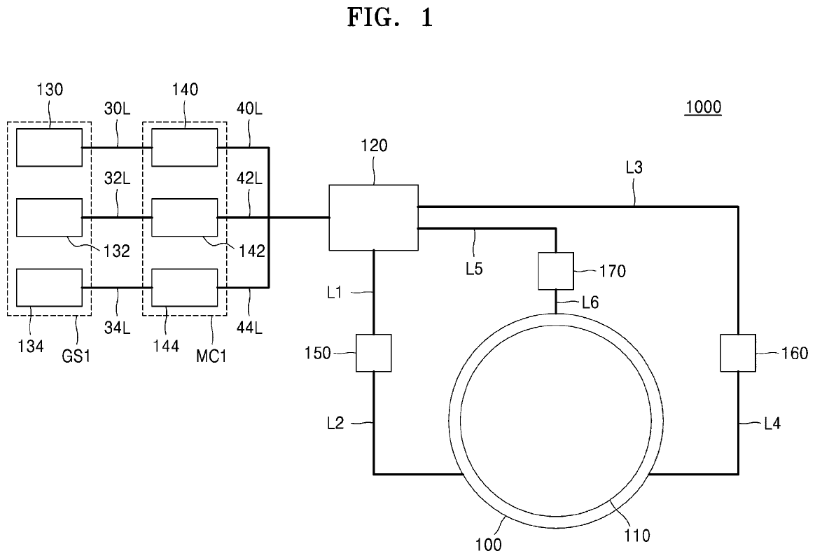

FIG. 1 shows an apparatus for manufacturing a semiconductor device 1000 (hereinafter, a first semiconductor manufacturing apparatus) according to some example embodiments.

The first semiconductor manufacturing apparatus 1000 of FIG. 1 may be a thin film deposition apparatus using plasma, but is not limited to such apparatuses. For example, the first semiconductor manufacturing apparatus 1000 may be used as an etching apparatus using plasma. The first semiconductor manufacturing apparatus 1000 may be an apparatus using multi-gas supply. Here, the multi-gas supply may mean a case of supplying two or more different types of gases. A thin film to be deposited may be a thin film including two or more components or three or more components. The multi-gas supply may include not only the supply of a gas containing a component directly constituting a thin film, but also the supply of a gas used together for thin film deposition, although not directly constituting a thin film.

The first semiconductor manufacturing apparatus 1000 includes a reaction chamber 100 in which plasma formation and thin film deposition occur and a plasma generator 110 configured to form plasma in the reaction chamber 100 by generating a radio frequency (RF) or a frequency of a microwave region. The plasma generator 110 irradiates microwaves to a gas supplied to the reaction chamber 100 for thin film deposition. As a result, a plasma gas including a thin film component may be formed in the reaction chamber 100.

The reaction chamber 100 and the plasma generator 110 are illustrated in a circular shape, but may not be limited to the circular shape. The first semiconductor manufacturing apparatus 1000 includes a gas splitter 120 and first to third flow controllers 150, 160, and 170 on the periphery of the reaction chamber 100. The gas splitter 120 is configured to mix a plurality of gases supplied from the gas supply source GS1 and supply a mixed gas to the reaction chamber 100. Therefore, the gas splitter 120 may serve as a gas mixer as well as a distributor to distribute the mixed gas. The first to third flow controllers 150, 160, and 170 are spaced apart from each other. The first to third flow controllers 150, 160, and 170 are positioned between the gas splitter 120 and the reaction chamber 100. The first to third flow controllers 150, 160, and 170 are configured to independently control the amount of gases supplied from the gas splitter 120 to the reaction chamber 100. The first flow controller 150 is positioned between the gas splitter 120 and the reaction chamber 100. The first flow controller 150 is able to independently control the amount of gases supplied to the reaction chamber 100 through first and second gas supply lines L1 and L2. The gas splitter 120 is connected with the first flow controller 150 through the first gas supply line L1. The first flow controller 150 is connected with the reaction chamber 100 through the second gas supply line L2. The second gas supply line L2 may be connected to a first position of the reaction chamber 100. The connection relation between the first flow controller 150 and the first and second gas supply lines L1 and L2 may be expressed as follows. That is, the first and second gas supply lines L1 and L2 may be regarded as one gas supply line, and it may be expressed that the first flow controller 150 is positioned in the one gas supply line. The expression may be equally applied to a connection relation between the flow controllers 160 and 170 and the gas supply lines.

The second flow controller 160 is positioned between the gas splitter 120 and the reaction chamber 100. The second flow controller 160 is able to independently control the amount of gases supplied to the reaction chamber 100 through third and fourth gas supply lines L3 and L4. The gas splitter 120 is connected with the second flow controller 160 through the third gas supply line L3. The second flow controller 160 is connected with the reaction chamber 100 through the fourth gas supply line L4. The fourth gas supply line L4 may be connected to a second position of the reaction chamber 100. The second position may differ from the first position.

The third flow controller 170 is positioned between the gas splitter 120 and the reaction chamber 100. The third flow controller 170 is able to independently control the amount of gases supplied to the reaction chamber 100 through fifth and sixth gas supply lines L5 and L6. The gas splitter 120 is connected with the third flow controller 170 through the fifth gas supply line L5. The third flow controller 170 is connected with the reaction chamber 100 through the sixth gas supply line L6.

The sixth gas supply line L6 may be connected to a third position of the reaction chamber 100. The third position differs from the first and second positions.

The first to third positions are on the same horizontal plane and may be symmetrically distributed. For example, the first to third positions may be maintained at a distance of 120° from each other. In some example embodiments, the gas supply lines may be connected to three or more places of the reaction chamber 100. That is, the three or more gas supply lines are directly and symmetrically connected to the reaction chamber 100 to supply a gas for thin film deposition to the reaction chamber 100. In this case, a distance between the gas supply lines may be less than 120°.

The first to third flow controllers 150, 160, and 170 are devices configured to control the amount of a fluid (e.g., gas) flowing through each gas supply line. Therefore, any device capable of performing such function may be used as the first to third flow controllers 150, 160, and 170 without particular limitation. In some example embodiments, the first to third flow controllers 150, 160, and 170 may be mass flow controllers (MFCs). In some example embodiments, the first to third flow controllers 150, 160, and 170 may be pressure control valves (PCVs). When the first to third flow controllers 150, 160, and 170 are the PCVs, the PCVs may be used in a relatively lower pressure environment than a pressure environment where the MFCs are used.

In the first semiconductor manufacturing apparatus 1000, the gas splitter 120 is positioned between the reaction chamber 100 and the gas supply source GS1 and a flow control unit MC1. In a gas supply path, the flow control unit MC1 is positioned between the gas supply source GS1 and the gas splitter 120. Accordingly, gases supplied to the gas splitter 120 may be flow into the gas splitter 120 from the gas supply source GS1 via the flow control unit MC1. The gas supply source GS1 may include first to third gas supply units 130, 132, and 134. According to the number of gas components used for thin film deposition, the gas supply source GS1 may be provided with three or more gas supply units. That is, the number of gas supply units provided at the gas supply source GS1 may increase in proportion to the number of gas components used for thin film deposition Types of gases supplied from the first to third gas supply units 130, 132, and 134 may differ. The first to third gas supply units 130, 132, and 134 are independently positioned and are configured to supply gases to the flow control unit MC1 through independently-provided gas supply lines 30L, 32L, and 34L, respectively. The flow control unit MC1 is configured to control a flow of a gas supplied from the gas supply source GS1 to the gas splitter 120 and may be configured to individually control gases introduced from the gas supply source GS1. Accordingly, the flow control unit MC1 may have the same number of the flow controllers as the number of gas supply units provided at the gas supply source GS1. For example, when the gas supply source GS1 has three gas supply units 130, 132, and 134, the flow control unit MC1 may have three flow controllers 140, 142, and 144. Accordingly, the gas supply units 130, 132, and 134 included in the gas supply source GS1 may correspond to the flow controllers 140, 142, and 144 provided at the flow control unit MC1 on a one-to-one basis. That is, the first gas supply unit 130 may correspond to the first flow controller 140, the second gas supply unit 132 may correspond to the second flow controller 142, and the third gas supply unit 134 may correspond to the third flow controller 144. The first gas supply unit 130 is connected with the first flow controller 140 through the seventh gas supply line 30L. The second gas supply line 132 is connected with the second flow controller 142 through the eighth gas supply line 32L. The third gas supply unit 134 is connected with the third flow controller 144 through the ninth gas supply line 34L. Gases having passed through the first to third flow controllers 140, 142, and 144 are supplied to the gas splitter 120 through a tenth gas supply line 40L, an eleventh gas supply line 42L, and a twelfth gas supply line 44L, respectively. The tenth to twelfth gas supply lines 40L, 42L, and 44L may be combined into one gas supply line before reaching the gas splitter 120. To this end, a component for joint of gas supply lines may be provided at a portion where the three gas supply lines 40L, 42L, and 44L meet together. Accordingly, gases may be introduced into the gas splitter 120 through one gas supply line.

As described above, as gases supplied to the reaction chamber 100 are introduced through the first to third flow controllers 150, 160, and 170, the amount of the gases supplied to the reaction chamber (100) through the gas supply lines L2, L4, and L6, respectively, may be accurately controlled. Accordingly, gases are uniformly supplied even over a large-sized wafer, and thus, a thin film with a uniform thickness is formed on a large-sized wafer, that is, a wafer with a large diameter, and a thickness of a deposited thin film may be uniformly controlled.

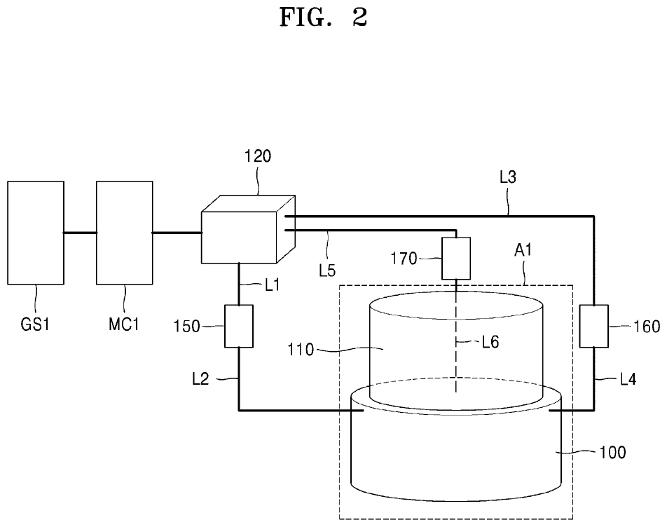

FIG. 2 is a three-dimensional view of the first semiconductor manufacturing apparatus 1000 of FIG. 1. A plasma generator (110) is positioned directly above the reaction chamber (100). The second, fourth and sixth gas supply lines L2, L4, and L6 are connected to an upper portion of the reaction chamber 100, but may be connected to a lower position than the upper end of the reaction chamber 100. The heights of positions where the second, fourth and sixth gas supply lines L2, L4, and L6 are connected to the reaction chamber 100 may be the same.

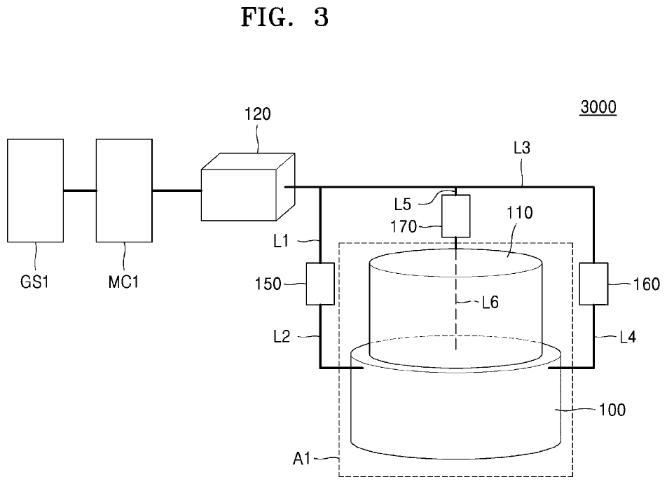

FIG. 3 shows an apparatus for manufacturing a semiconductor device (hereinafter, a second semiconductor manufacturing apparatus 3000) according to some example embodiments. Only parts different from those in FIGS. 1 and 2 will be described.

Referring to FIG. 3, the fifth gas supply line L5 is not directly connected with the gas splitter 120. The fifth gas supply line L5 is directly connected to the third gas supply line L3. The fifth gas supply line L5 connects the third gas supply line L3 with the third flow controller 170. Accordingly, gases supplied from the gas splitter 120 are transmitted to the third flow controller 170 through the third and fifth gas supply lines L3 and L5. The first gas supply line L1 is also not directly connected to the gas splitter 120. The first gas supply line L1 is directly connected to the third gas supply line L3. Accordingly, gases supplied from the gas splitter 120 are transmitted to the first flow supplier 150 through the third gas supply line L3 and the first gas supply line L1.

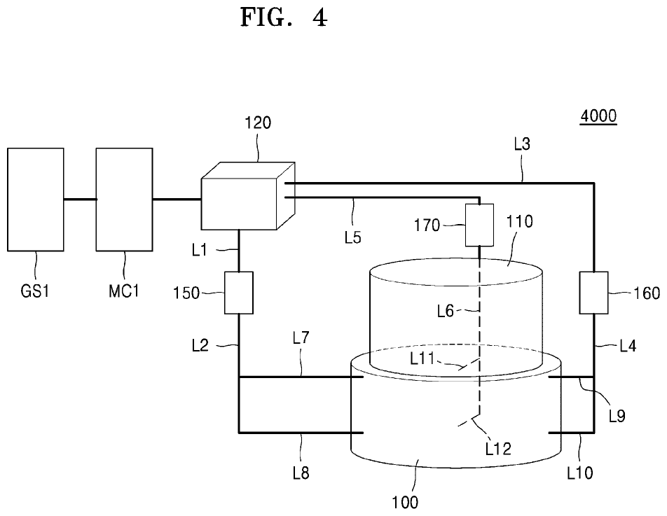

FIG. 4 shows an apparatus for manufacturing a semiconductor device (hereinafter, a third semiconductor manufacturing apparatus 4000) according to some example embodiments. Only parts different from those in FIGS. 1 and 2 will be described.

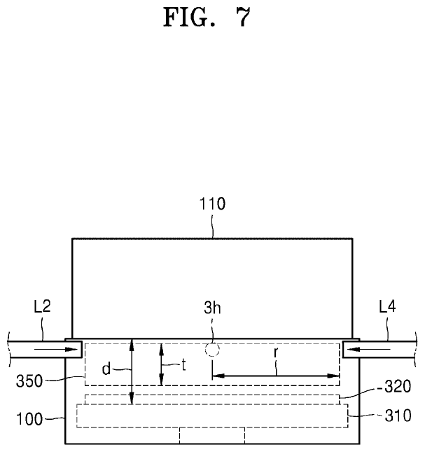

Referring to FIG. 4, the second gas supply line L2 is branched into the seventh gas supply line L7 and the eighth gas supply line L8 to be connected to the reaction chamber 100. The seventh gas supply line (L7) is connected to a position close to the upper end of the reaction chamber (100). The eighth gas supply line L8 may be connected below the seventh gas supply line L7. That is, the eighth gas supply line L8 may be connected to a position further away from the upper end of the reaction chamber 100 than the seventh gas supply line L7. In other words, the eighth gas supply line L8 may be connected to the reaction chamber 100 between a position where the seventh gas supply line L7 is connected and the stage on which a substrate is loaded (310 in FIG. 7). The eighth gas supply line L8 may be connected to a position close to the stage 310. Diameters of the seventh and eighth gas supply lines L7 and L8 may be the same or different.

The fourth gas supply line L4 is branched into the ninth gas supply line L9 and the tenth gas supply line L10 to be connected to the reaction chamber 100. The ninth gas supply line L9 may be connected to a position close to the upper end of the reaction chamber 100. The ninth gas supply line L9 is connected to the reaction chamber 100 at the same height as the seventh gas supply line L7. The tenth gas supply line L10 is positioned below the ninth gas supply line L9. A position where the tenth gas supply line L10 is connected to the reaction chamber 100 is lower than a position where the ninth gas supply line L9 is connected to the reaction chamber 100. The tenth gas supply line L10 is connected to the reaction chamber 100 between the ninth gas supply line L9 and the stage 310. A position where the tenth gas supply line L10 is connected to the reaction chamber 100 is closer to the stage 310 than the upper end of the reaction chamber 100. The tenth gas supply line L10 is connected to the reaction chamber 100 at the same height as the eighth gas supply line L8. That is, heights of positions where the eighth gas supply line L8 and the tenth gas supply line L10 are connected to the reaction chamber 100 may be the same. The sixth gas supply line L6 is branched into the eleventh gas supply line L11 and the twelfth gas supply line L12 to be connected to the reaction chamber 100. The eleventh gas supply line L11 is connected to a position close to the upper end of the reaction chamber 100. The twelfth gas supply line L12 is connected to the reaction chamber 100 at a lower position than the eleventh gas supply line L11. A connection relation between the twelfth gas supply line L12 and the reaction chamber 100 is the same as a connection relation between the eighth gas supply line L8 and the reaction chamber 100 or a connection relation between the tenth gas supply line L10 and the reaction chamber 100.

The seventh, ninth and eleventh gas supply lines L7, L9, and L11 may be connected to the reaction chamber 100 so that the seventh, ninth and eleventh gas supply lines L7, L9, and L11 have the same symmetry as the second, fourth and sixth gas supply lines L2, L4, and L6. The eighth, tenth and twelfth gas supply lines L8, L10, and L12 may also be connected to the reaction chamber 100 to have the symmetry.

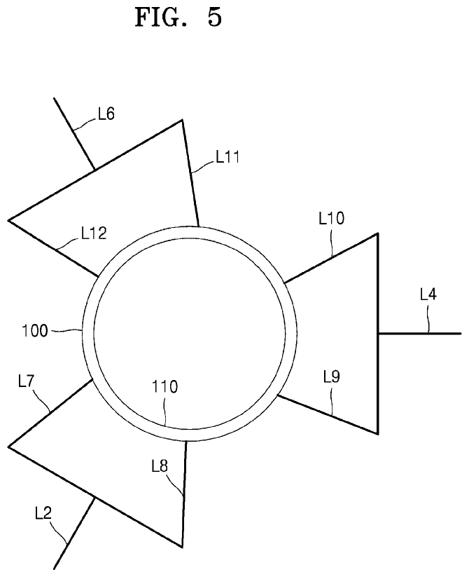

In some example embodiments, a portion (e.g., three gas supply lines) and the rest of the seventh to twelfth gas supply lines L7 to L12 may be alternately arranged from each other while maintaining the symmetry. For example, the seventh, ninth and eleventh gas supply lines L7, L9, and L11 or the eighth, tenth and twelfth gas supply lines L8, L10, and L12 may be rotated at an angle of 60° to right or left sides at the position of FIG. 4. FIG. 5, as an example, shows the case. For convenience of illustration, FIG. 5 briefly shows only the reaction chamber 100 and a wiring connected thereto.

Referring to FIG. 5, the eighth gas supply line L8 is positioned between the seventh gas supply line L7 and the ninth gas supply line L9. An angle between the eighth gas supply line L8 and the seventh and ninth gas supply lines L7 and L9 may be about 60°. The tenth gas supply line L10 is positioned between the ninth gas supply line L9 and the eleventh gas supply line L11. An angle between the tenth gas supply line L10 and the ninth and eleventh gas supply lines L9 and L11 may be about 60°. The twelfth gas supply line L12 is positioned between the eleventh gas supply line L11 and the seventh gas supply line L7. An angle between the twelfth gas supply line L12 and the seventh and eleventh gas supply lines L7 and L11 may be about 60°. In FIG. 5, the seventh, ninth, and eleventh gas supply lines L7, L9, and L11 are rotationally symmetrical to each other at 120° intervals. The eighth, tenth and twelfth gas supply lines L8, L10, and L12 are also rotationally symmetrical to each other at 120° intervals The seventh to twelfth gas supply lines L7 to L12 are rotationally symmetrical to each other at 60° intervals.

The case that the second, fourth, and sixth gas supply lines L2, L4, and L6 of the third semiconductor manufacturing apparatus 4000 shown in FIG. 4 are branched into two gas supply lines, respectively, may be equally applied to the second semiconductor manufacturing apparatus 3000 of FIG. 3.

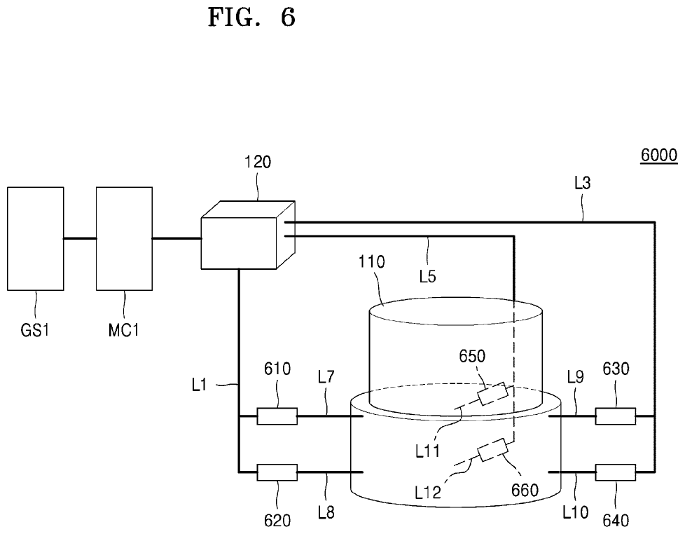

FIG. 6 shows an apparatus for manufacturing a semiconductor device (hereinafter, a fourth semiconductor manufacturing apparatus 6000) according to some example embodiments. The fourth semiconductor manufacturing apparatus 6000 may be a modification of the third semiconductor manufacturing apparatus 4000 of FIG. 4. Therefore, only parts different from FIG. 4 will be described.

Referring to FIG. 6, the seventh and eighth gas supply lines L7 and L8 are connected to the first gas supply line L1. A flow controller is not provided in the first gas supply line L1. A first flow controller 610 is provided in the seventh gas supply line L7, and a second flow controller 620 is provided in the eighth gas supply line L8. The ninth and tenth gas supply lines L9 and L10 are connected to the third gas supply line L3. A third flow controller 630 is provided in the ninth gas supply line L9. A fourth flow controller 640 is provided in the tenth gas supply line L10. A flow controller is not provided in the third gas supply line L3. The eleventh and twelfth gas supply lines L11 and L12 are connected to the fifth gas supply line L5. A fifth flow controller 650 is provided in the eleventh gas supply line L11, and a sixth flow controller 660 is provided in the twelfth gas supply line L12. A flow controller is not provided in the fifth gas supply line L5.

The case that the first, third, and fifth gas supply lines L1, L3, and L5 of the fourth semiconductor manufacturing apparatus 6000 shown in FIG. 6 are branched into two gas supply lines, respectively, and the flow controllers 610, 620, 630, 640, 650, and 660 are provided in the branched gas supply lines L7-L12 may be equally applied to the second semiconductor manufacturing apparatus 3000 of FIG. 3.

FIG. 7 is a front view of a first region Al including the reaction chamber 100 and the plasma generator 110 of FIG. 2.

Referring to FIG. 7, the second and fourth gas supply lines L2 and L4 are connected to a slightly lower position than the upper end in the vicinity of the upper end of the reaction chamber 100. The second and fourth gas supply lines L2 and L4 are connected at the same height. A reference numeral 3h represents a gas inlet hole formed at the same height as a portion where the second and fourth gas supply lines L2 and L4 are connected with the reaction chamber 100. The gas inlet hole 3h may be a portion where the sixth gas supply line L6 is connected with the reaction chamber 100. Therefore, a gas supplied through the sixth gas supply line L6 is introduced into the reaction chamber 100 through the gas inlet hole 3h. A reference numeral 310 represents the stage. A reference numeral 320 represents a substrate loaded on the stage 310. The substrate 320 may be a wafer. A thin film may be deposited on the substrate 320. Plasma is formed inside the reaction chamber 100 as microwaves generated from the plasma generator 110 are irradiated to gases supplied to the reaction chamber 100 through the second, fourth, and sixth gas supply lines L2, L4, and L6. The plasma may be formed between the plasma generator 110 and the stage 310. A reference numeral 350 represents a plasma forming space where plasma is formed in the reaction chamber 100. The plasma forming space 350 may be positioned between the plasma generator 110 and the substrate 320. A radius (r) of the plasma forming space 350 may be greater than a distance (d) between the plasma generator 110 and the stage 310. An internal radius of the reaction chamber 100 is greater than that of the plasma forming space 350. As a result, the reaction chamber 100 has a small and thin form with an aspect ratio less than 1. A thickness (t) of the plasma forming space 350 is less than or equal to the distance (d) between the plasma generator 110 and the stage 310, and thus, an aspect ratio (t/r) of the plasma forming space 350 may also be 1 or less.

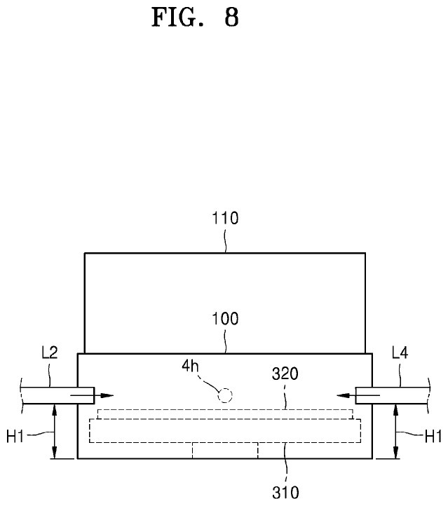

Meanwhile, positions where the second, fourth, and sixth gas supply lines L2, L4, and L6 are connected to the reaction chamber 100 may be positioned further below than those shown in FIG. 7. For example, as shown in FIG. 8, positions where the second, fourth, and sixth gas supply lines L2, L4, and L6 are connected to the reaction chamber 100 may be closer to the substrate 320 than the upper end of the reaction chamber, and may be at the same height H1 from the bottom of the reaction chamber 100. A reference numeral 4h indicates a gas inlet hole formed at the same height as a portion where the second and forth gas supply lines L2 and L4 are connected with the reaction chamber 100.

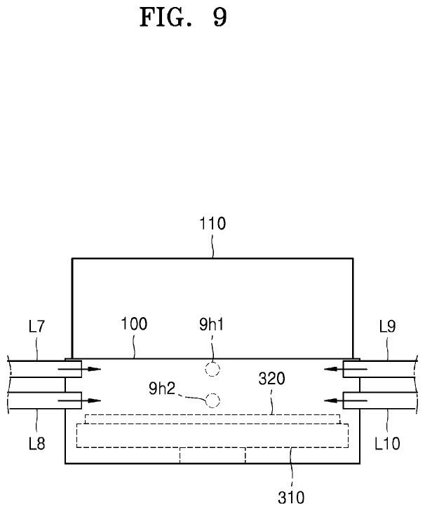

FIG. 9 shows a case in which FIGS. 7 and 8 are combined. That is, FIG. 9 may be a front view of a region including the reaction chamber 100 and the plasma generator 110 of the third semiconductor manufacturing apparatus 3000 or the fourth semiconductor manufacturing apparatus.

Referring to FIG. 9, the seventh and ninth gas supply lines L7 and L9 are connected to both sides directly below the upper end of the reaction chamber 100, respectively. The eighth gas supply line L8 is connected between the seventh gas supply line L7 and the substrate 320. The seventh and eighth gas supply lines L7 and L8 are connected to the same first side of the reaction chamber 100. The tenth gas supply line L10 is connected between the ninth gas supply line L9 and the substrate 320. The ninth and tenth gas supply lines L9 and L10 are connected to the same second side of the reaction chamber 100. The seventh and ninth gas supply lines L7 and L9 are connected to the reaction chamber 100 at the same height. The eighth and tenth gas supply lines L8 and L10 are connected to the reaction chamber 100 at the same height. A first hole 9h1 positioned between the seventh and ninth gas supply lines L7 and L9 while flush with the seventh and ninth gas supply lines L7 and L9 represents a position where the eleventh gas supply line (L11 of FIGS. 4 and 6) is connected to the reaction chamber 100. A second hole 9h2 positioned between the eighth and tenth gas supply lines L8 and L10 while flush with the eighth and tenth gas supply lines L8 and L10 represents a position where the twelfth gas supply line (L12 of FIGS. 4 and 6) is connected to the reaction chamber 100. The first and second holes 9h1 and 9h2 are vertically formed side by side.

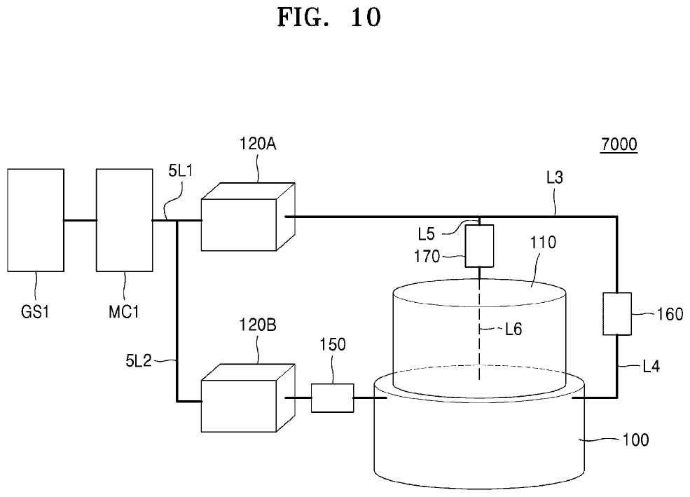

FIG. 10 shows a semiconductor manufacturing apparatus (hereinafter, a fifth semiconductor manufacturing apparatus) according to some example embodiments.

Referring to FIG. 10, the fifth semiconductor manufacturing apparatus 7000 includes a case in which a plurality of gas splitters 120A and 120B are positioned between the reaction chamber 100 and the flow controller unit MC1. The first gas splitter 120A is configured to mix gases supplied from the flow control unit MC1 and supply the mixed gas to the second and third flow controllers 160 and 170. The first gas splitter 120A is connected with the flow control unit MC1 through a thirteenth gas supply line 5L1. A second gas splitter 1208 is configured to mix gases supplied from the flow control unit MC1 and supply the mixed gas to the first flow controller 150. The second gas splitter 1208 is connected with the thirteenth gas supply line 5L1 through a fourteenth gas supply line 5L2. A flow controller connected to the first and second gas splitters 120A and 1208 among the first to third flow controllers 150, 160, and 170 may be optional. Therefore, a flow controller connected to the first gas splitter 120A is not limited to the first and second flow controllers 160 and 170, and a flow controller connected to the second gas splitter 120B is not limited the first flow controller 150. The rest of the fifth semiconductor manufacturing apparatus 7000 except for the first and second gas splitters 120A and 120B may be the same as the second semiconductor manufacturing apparatus 3000 described with reference to FIGS. 3, 7, and 8.

Moreover, as shown in FIGS. 4 and 6, the case that a gas supply line connected to the reaction chamber 100 are branched into two lines may be equally applied to the fifth semiconductor manufacturing apparatus 7000. Therefore, the gas supply line connecting the second gas splitter 120B with the reaction chamber 100 may be connected to the reaction chamber 100 while branched into two lines, and the fourth and sixth gas supply lines L4 and L6 may be branched into two lines to be connected to the reaction chamber 100, respectively.

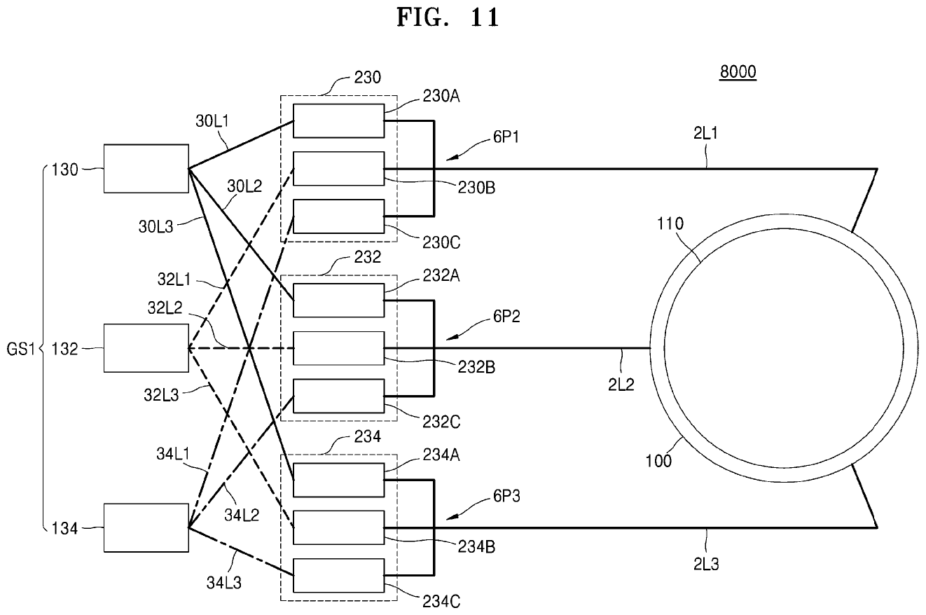

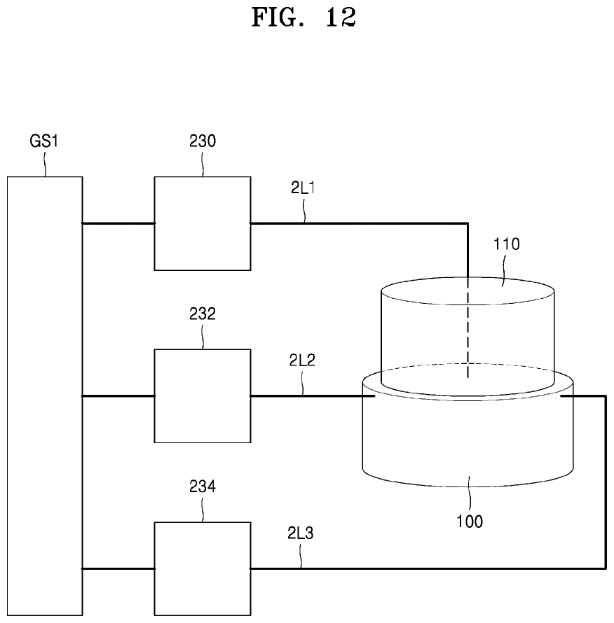

FIG. 11 is a plan view of a semiconductor manufacturing apparatus (hereinafter, a sixth semiconductor manufacturing apparatus 8000) according to some example embodiments. FIG. 12 is a three-dimensional view of the sixth semiconductor manufacturing apparatus 8000 of FIG. 11. The same reference numerals are used for the same members as those described in the above-described semiconductor manufacturing apparatus, and descriptions thereof will be omitted.

Referring to FIGS. 11 and 12, the sixth semiconductor manufacturing apparatus 8000 includes a reaction chamber 100 and a plasma generator 110 provided thereon. The sixth semiconductor manufacturing apparatus 8000 also includes a gas supply source GS1 and first to third flow control units 230, 232, and 234. The first to third flow controllers 230, 232, and 234 are positioned between the reaction chamber 100 and the gas supply source GS1. The first flow control unit 230 is connected with the reaction chamber 100 through the first gas supply line 2L1. The second flow control unit 232 is connected with the reaction chamber 100 through the second gas supply line 2L2. The third flow control unit 234 is connected with the reaction chamber 100 through the third gas supply line 2L3. The first flow controller 230 includes first to third flow controllers 230A, 230B, and 230C. Each of the first to third flow controllers 230A, 230B, and 230C may, for example, be an MFC. Three gas supply lines connected to the first to third flow controllers 230A, 230B, and 230C, respectively, are connected to the first gas supply line 2L1. Therefore, gases supplied through the first to third flow controllers 230A, 230B, and 230C are mixed with each other while flowing into one first gas supply line 2L1. Accordingly, a set amount of gases required for thin film deposition may be supplied to the reaction chamber 100 through the first gas supply line 2L1. A flow controller different from the first to third flow controllers 230A, 230B, and 230C, such as a PCV, may be further provided at a first portion 6P1 where three gas supply lines connected to the first to third flow controllers 230A, 230B, and 230C, respectively, meet the first gas supply line 2L1.

The second flow control unit 232 includes fourth to six flow controllers 232A, 232B, and 232C. Each of the fourth to sixth flow controllers 232A, 232B, and 232C may be, for example, an MFC. Three gas supply lines connected to the fourth to sixth controllers 232A, 232B, and 232C, respectively, are connected to one second gas supply line 2L2. Accordingly, gases supplied through the fourth to sixth controllers 232A, 232B, and 232C are mixed with each other while flowing into the second gas supply line 2L2. Thus, a set amount of gases required for thin film deposition may be supplied to the reaction chamber 100 through the second gas supply line 2L2. A flow controller different from the fourth to sixth flow controllers 232A, 232B, and 232C, such as a PCV, is further provided at a second portion 6P2 where the three gas supply lines connected to the fourth to sixth flow controllers 232A, 232B, and 232C, respectively, meet the second gas supply line 2L2.

The third flow control unit 234 includes the seventh to ninth flow controllers 234A, 234B, and 234C. Each of the seventh to ninth flow controllers 234A, 234B, and 234C, may be, for example, an MFC. Three gas supply lines connected to the seventh to ninth flow controllers 234A, 234B, and 234C, respectively, may be connected to one third gas supply line 2L3. Accordingly, gases supplied through the seventh to ninth controllers 234A, 234B, and 234C are mixed with each other while flowing into the third gas supply line 2L3. Thus, a set amount of gases required for thin film deposition may be supplied to the reaction chamber 100 through the third gas supply line 2L3. A flow controller different from the seventh to ninth flow controllers 234A, 234B, and 234C, such as a PCV, is further provided at a third portion 6P3 where the three gas supply lines connected to the seventh to ninth flow controllers 234A, 234B, and 234C, respectively, meet the third gas supply line 2L3. In some example embodiments, the amount of a gas supplied to the reaction chamber 100 through each of the gas supply lines 2L1, 2L2, and 2L3 during thin film deposition may be constant. In some example embodiments, the amount of gases supplied to the reaction chamber 100 through each of the gas supply lines 2L1, 2L2, and 2L3 during thin film deposition may be different, for example, the amount of gases supplied to the reaction chamber 100 through each of the second and third gas supply lines 2L2 and 2L3 are kept constant, and the amount of a gas supplied to the reaction chamber 100 through the first gas supply line 2L1 may be greater than the amount of gases supplied to the reaction chamber through each of the second and third gas supply lines 2L2 and 2L3. Contents regarding the position where the first to third gas supply lines 2L1, 2L2, and 2L3 are connected to the reaction chamber 100 may be the same as the description about the position where first to third gas supply lines L1 to L3 are connected to the reaction chamber 100, described in the first semiconductor manufacturing apparatus 1000.

Next, a connection relationship between the gas supply source GS1 and the first to third flow control units 230, 232, and 234 will be described.

The first gas supply unit 130 of the gas supply source GS1 is arranged to supply a first gas to the first to third flow control units 230, 232, and 234. The second gas supply unit 132 is arranged to supply a second gas to the first to third flow control units 230, 232, and 234. The third gas supply unit 134 is arranged to supply a third gas to the first to third flow control units 230, 232, and 234. The first to third gases may be different from each other.

More specifically, the first gas is supplied, from the first gas supply unit 130, to a first flow controller 230A of the first flow control unit 230, a fourth flow controller 232A of the second flow control unit 232, and a seventh flow controller 234A of the third flow control unit 234, respectively. To this end, the first gas supply unit 130 is connected with the first flow controller 230A through the fourth gas supply line 30L1, and the first gas supply unit 130 is connected with the fourth flow controller 232A through the fifth gas supply line 30L2, and the first gas supply unit 130 is connected with the seventh flow controller 234A through the sixth gas supply line 30L3.

The second gas is supplied, from the second gas supply unit 132, to a second flow controller 230B of the first flow control unit 230, to a fifth flow controller 232B of the second flow control unit 232, and an eighth flow controller 234B of the third flow control unit 234, respectively. To this end, the second gas supply unit 132 is connected with the second flow controller 230B through the seventh gas supply line 32L1, the second gas supply unit 132 is connected with the fifth flow controller 232B through the eighth gas supply line 32L2, and the second gas supply unit 132 is connected with the eighth flow controller 234B through the ninth gas supply line 32L3.

The third gas is supplied, from the third gas supply unit 134, to a third flow controller 230C of the first flow control unit 230, a sixth flow controller 232C of the second flow control unit 232, and a ninth flow controller 234C of the third flow control unit 234, respectively. To this end, the third gas supply unit 134 is connected with the third flow controller 230C through a tenth gas supply line 34L1, the third gas supply unit 134 is connected with the sixth flow controller 232C through an eleventh gas supply line 34L2, and the third gas supply unit 134 is connected with the ninth flow controller 234C through a twelfth gas supply line 34L3.

The number of gas supply units provided at the gas supply source GS1 may be the same as the number of flow controllers provided at the flow control units 230, 232, and 234, respectively. Accordingly, as the number of gas supply units provided at the gas supply source GS1 increases, the number of flow controllers provided at the flow control units 230, 232, and 234, respectively, also increases. That is, as the number of gas components required for thin film deposition increases, the number of gas supply units provided at the gas supply source GS1 as well as the number of flow controllers provided at the flow control units 230, 232, and 234, respectively, also increase.

As show in FIGS. 4 and 6, the case that a gas supply line connected to the reaction chamber 100 is branched into two lines may be equally applied to the sixth semiconductor manufacturing apparatus 8000. Therefore, the first to third gas supply lines 2L1, 2L2, and 2L3 may be connected to the reaction chamber 100 while each branched into two lines. That is, six gas supply lines are directly connected to the reaction chamber 100.

The semiconductor manufacturing devices according to some example embodiments include configuration capable of independently controlling the amount of gases respectively supplied to the plurality of gas supply lines connected to the reaction chamber. Accordingly, the amount of a gas supplied to the reaction chamber through each gas supply line is uniformly controlled or the amount of a gas supplied through a specific gas supply line may be controlled differently from gases supplied through the rest of the gas supply lines. Accordingly, the amount of gases supplied to the reaction chamber are independently controlled by each gas supply line to actively correspond to an environment where a size of a substrate changes. As a result, when using the semiconductor manufacturing devices according to some example embodiments, it is possible to uniformly supply gases to the entire surface of the substrate regardless of a size of the substrate, and thus, a thin film may also be formed to have a uniform thickness over the entire substrate.

It should be understood that some example embodiments described herein should be considered in a descriptive sense only and not for purposes of limitation. Descriptions of features or aspects within each example embodiment should typically be considered as available for other similar features or aspects in other example embodiments. While one or more example embodiments have been described with reference to the figures, it will be understood by those of ordinary skill in the art that various changes in form and details may be made therein without departing from the spirit and scope as defined by the following claims.

What is claimed is:

1. An apparatus for manufacturing a semiconductor device, the apparatus comprising:
a reaction chamber having a stage on which a substrate is loaded, the reaction chamber configured to have set plasma formed over the stage;
a plurality of gas supply lines connected to the reaction chamber;
a plurality of flow controllers provided at the plurality of gas supply lines, respectively, to control an amount of a gas supplied to the reaction chamber; and
a gas splitter configured to supply a mixed gas to the plurality of flow controllers.

2. The apparatus of claim 1, further comprising:
a flow control unit connected to the gas splitter.

3. The apparatus of claim 2, further comprising:
a gas supply source connected to the flow control units.

4. The apparatus of claim 2, wherein the flow control unit comprise:
a first flow controller configured to control a supply amount of a first gas;
a second flow controller configured to control a supply amount of a second gas different from the first gas; and
a third flow controller configured to control a supply amount of a third gas different from the first and second gases.

5. The apparatus of claim 1, wherein the gas splitter comprises:
a first gas splitter connected to some of the plurality of flow controllers; and
a second gas splitter connected to the rest of the plurality of flow controllers.

6. The apparatus of claim 1, wherein the plurality of flow controllers are mass flow controllers (MFCs) or pressure control valves (PCVs).

7. The apparatus of claim 1 wherein connection positions of the plurality of gas supply lines with respect to the reaction chamber are symmetrically distributed.

8. The apparatus of claim 1, wherein the plurality of gas supply lines are connected to be closer to an upper end of the reaction chamber than to the stage.

9. The apparatus of claim 1, wherein the plurality of gas supply lines are connected to be closer to the stage than to an upper end of the reaction chamber.

10. The apparatus of claim 1, wherein
a portion of the plurality of gas supply lines are connected to the reaction chamber between an upper end of the reaction chamber and the stage, and
a rest of the plurality of gas supply lines are connected to the reaction chamber between the portion of the plurality of gas supply lines and the stage.

11. The apparatus of claim 1, wherein a ratio (d/r) of a radius (r) of a plasma forming space inside the reaction chamber to a distance (d) between an upper end of the reaction chamber and the stage is less than 1.

12. The apparatus of claim 1, further comprising:
a plasma generator arranged on the reaction chamber and having a radio frequency (RF) or a frequency in a microwave region.

13. The apparatus of claim 1, wherein the reaction chamber is a chamber for thin film deposition.

14. An apparatus for manufacturing a semiconductor device, the apparatus comprising:
a reaction chamber having a stage on which a substrate is loaded, the reaction chamber configured to have set plasma is formed over the stage;
a plurality of gas supply lines connected to the reaction chamber; and
a plurality of flow control units configured to control an amount of a gas supplied to the reaction chamber, and connected to the plurality of gas supply lines on a one-to-one basis,
each of the plurality of flow control units comprising a plurality of flow controllers.

15. The apparatus of claim 14, wherein the plurality of flow controllers are provided in a same number as all different gas components supplied to the reaction chamber.

16. The apparatus of claim 14, further comprising:
a gas supply source for supplying gases to each of the plurality of flow control units.

17. The apparatus of claim 16, wherein the gas supply source comprises gas supply units provided in a same number as the plurality of flow controllers respectively provided at the plurality of flow control units.

18. The apparatus of claim 17, wherein the gas supply source comprises:
a first gas supply unit for supplying a first gas to each of the plurality of flow control units; and
a second gas supply unit for supplying a second gas different from the first gas to each of the plurality of flow control units.

19. The apparatus of claim 18, wherein the gas supply source further comprises a third gas supply unit for supplying a third gas different from the first and second gases to each of the plurality of flow control units.

20. The apparatus of claim 14, wherein the plurality of gas supply lines are connected to be closer to an upper end of the reaction chamber than to the stage.

21. The apparatus of claim 14, wherein the plurality of gas supply lines are connected to be closer to the stage than to an upper end of the reaction chamber.

22. The apparatus of claim 14, wherein a portion of the plurality of gas supply lines are connected to the reaction chamber between an upper end of the reaction chamber and the stage, and a rest of the plurality of gas supply lines are connected to the reaction chamber between the portion and the stage.

23. The apparatus of claim 14, wherein a ratio (d/r) of the radius (r) of a plasma forming space inside the reaction chamber to a distance (d) between an upper end of the reaction chamber and the stage is less than 1.

24. The apparatus of claim 14, further comprising:
a plasma generator arranged on the reaction chamber and having an RF or a frequency in a microwave region.
